(19) United States
(12) Patent Application Publication
(10) Pub. No.: US 2026/0368394 A1
(43) Pub. Date: Nov. 19, 2026

(54) PROCESSING DEVICE, PROCESSING METHOD, AND PROGRAM

(71) Applicant: NTT, Inc., Tokyo (JP)

(72) Inventors: Aya Suzuki, Musashino-shi, Tokyo (JP); Toru Nakamura, Musashino-shi, Tokyo (JP); Masaki HISADA, Musashino-shi, Tokyo (JP)

(21) Appl. No.: 19/477,164

(22) PCT Filed: May 1, 2023
(86) PCT No.: PCT/JP2023/017016

§ 371 Date: Oct. 21, 2025

(51) Int. Cl. G06F 30/20

(52) U.S. Cl. CPC G06F 30/20

(57) ABSTRACT

A processing device includes an acquisition unit that acquires state variables that configure an ecosystem model and a model generation unit that identifies taxonomic positions of the acquired state variables, acquires a model template from the number of the identified taxonomic positions for each classification, and generates a model in which the state variables are incorporated in the acquired model template.

### TECHNICAL FIELD

The present disclosure relates to a processing device, a processing method, and a program.

### BACKGROUND ART

There is a closed recirculatory aquaculture system that artificially configures a part of a marine ecosystem on land or the like (Non Patent Literature 1). The closed recirculatory aquaculture system is an environment that artificially configures a part of a marine ecosystem on land or the like. The closed circulating aquaculture system has a configuration similar to that of general aquaponics, and thus may be referred to as ecosystem aquaponics.

As a technology for predicting a substance amount and a biological amount in a marine ecosystem, there is a marine ecosystem model. As an example of a known marine ecosystem model, there is nutrient, phytoplankton, zooplankton, and detritus (NPZD) for a lower level ecosystem model (Non Patent Literature 2). The NPZD model is a simple model that directly expresses ecosystem interactions. The NPZD model indicates a substance balance between nutrient (N), phytoplankton (P), zooplankton (Z), and detritus (D). Nutrient, phytoplankton, zooplankton, and detritus may be called state variables because the amounts of nutrients, phytoplankton, zooplankton, and detritus vary depending on a state of the ecosystem. Non Patent Literature 2 discloses a method of predicting a substance amount and a biological amount of each state variable using a model.

There is a database that identifies taxonomic positions of substances and organisms that configure a marine ecosystem (Non Patent Literature 3). Non Patent Literature 3 has a function of retrieving and integrating global distribution and diversity data of marine organisms. Non Patent Literature 3 is an information system related to distribution and diversity of marine organisms that is the largest in the world. Non Patent Literature 3 has data based on the Darwin Core format that is a world standard format. The data includes at least a taxonomic position, a distribution, and an appearance time.

### CITATION LIST

### Non Patent Literature

Non Patent Literature 1: Toshio Takeuchi, “Closed Ecological Recirculating Aquaculture Systems”, Dec. 30, 2017, Application of Recirculating Aquaculture Systems in Japan (pp.279-298), 2017

Non Patent Literature 2: Karline Soetaert and Peter M. J. Herman, “A Practical Guide to Ecological Modelling”, Springer, 2009

Non Patent Literature 3: OBIS (Ocean Biogeographic Information System), [retrieved on Apr. 10, 2023], Internet <URL: https://obis.org/>

### SUMMARY OF INVENTION

### Technical Problem

In an environment that artificially configures a part of a marine ecosystem on land or the like, such as ecosystem aquaponics, it may be difficult to predict a substance amount and a biological amount of each state variable in some cases.

First, a known marine ecosystem model such as the NPZD model of Non Patent Literature 2 is a fixed model on the premise of the ocean. There is no disclosure of a prediction in the environment that artificially configures a part of the marine ecosystem on land or the like.

Furthermore, in ecosystem aquaponics, there are the four types of feed plants, nutrients, detritus, and organisms to be cultivated, or five types obtained by adding feed zooplankton to the four types. In this way, in ecosystem aquaponics, there is only a part of the marine ecosystem. In ecosystem aquaponics, since there is artificial inflow to and outflow from an aquaculture tank, the flow of substances in the environment is different from that in the Accordingly, the marine ecosystem model cannot be applied to ecosystem aquaponics.

The present disclosure has been made in view of the above circumstances, and an object of the present disclosure is to provide a technology capable of generating an ecosystem model according to an environment.

### Solution to Problem

According to an aspect of the present disclosure, a processing device includes: an acquisition unit configured to acquire state variables that configure an ecosystem model; and a model generation unit configured to identify taxonomic positions of the acquired state variables, acquire a model template from the number of the identified taxonomic positions for each classification, and generate a model in which the state variables are incorporated in the acquired model template.

According to another aspect of the present disclosure, a processing method includes: acquiring state variables that configure an ecosystem model by a computer; and identifying taxonomic positions of the acquired state variables, acquiring a model template from the number of the identified taxonomic positions for each classification, and generating a model in which the state variables are incorporated in the acquired model template by the computer.

According to still another aspect of the present disclosure, a program causes a computer to function as: an acquisition unit configured to acquire state variables that configure an ecosystem model; and a model generation unit configured to identify taxonomic positions of the acquired state variables, acquire a model template from the number of the identified taxonomic positions for each classification, and generate a model in which the state variables are incorporated in the acquired model template.

### Advantageous Effects of Invention

According to the present disclosure, it is possible to provide a technology capable of generating an ecosystem model according to an environment.

### BRIEF DESCRIPTION OF DRAWINGS

FIG. 1 is a sequence diagram illustrating a processing method according to an embodiment of the present disclosure.

FIG. 2 is a diagram illustrating an example of a state variable received from a user terminal and a taxonomic position of the state variable.

FIG. 3 is a diagram illustrating an example of a model generated by a processing device.

FIG. 4 is a diagram illustrating an example of a model corrected by a processing device.

FIG. 5 is a diagram illustrating functional blocks of the processing device according to the embodiment of the present disclosure.

FIG. 6 is a diagram illustrating an example of a data structure and data of model template data.

FIG. 7 is a diagram illustrating an example of a data structure and data of condition data.

FIG. 8 is a diagram illustrating an example of a data structure and data of result rate data.

FIG. 9 is a flowchart illustrating an acquisition process by an acquisition unit.

FIG. 10 is a flowchart (part 1) illustrating a generation process by a model generation unit.

FIG. 11 is a flowchart (part 2) illustrating the generation process by the model generation unit.

FIG. 12 is a flowchart illustrating a prediction process by a prediction unit.

FIG. 13 is a diagram illustrating a hardware configuration of a computer used in a processing device.

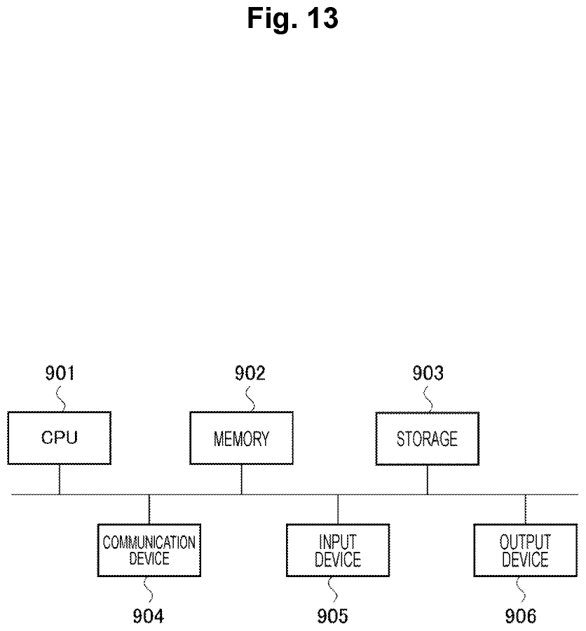

### DESCRIPTION OF EMBODIMENTS

Hereinafter, embodiments of the present disclosure will be described with reference to the drawings. In the drawings, the same portions are denoted by the same reference signs, and description thereof will be omitted.

### Processing Method

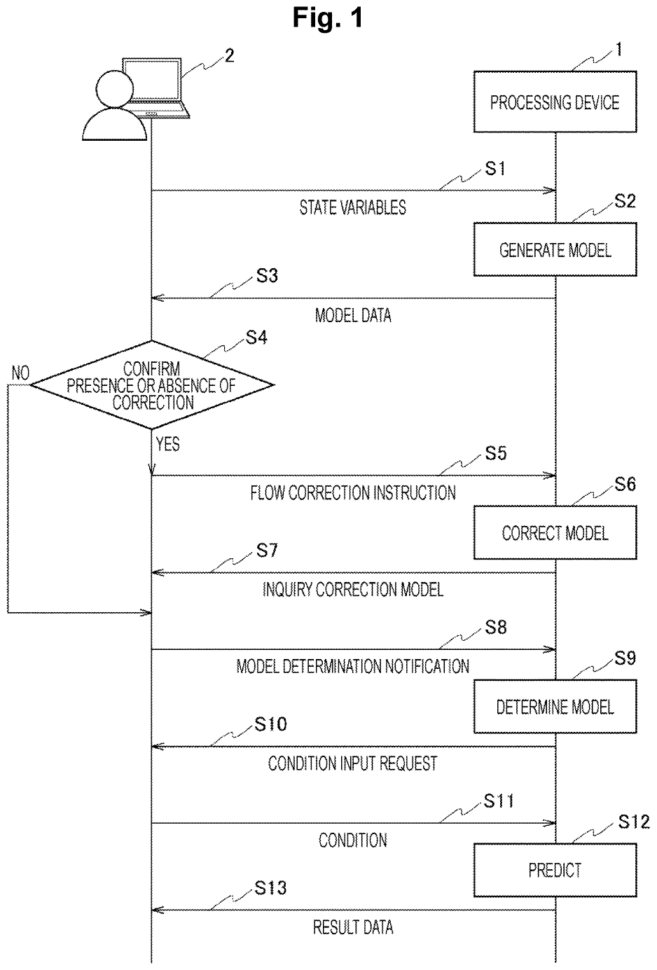

A processing method according to the present disclosure will be described with reference to FIG. 1. In FIG. 1, an ecosystem model according to an environment is generated, and changes in a substance amount and a biological amount in the ecosystem model are predicted using the generated ecosystem model.

In step S1, a processing device 1 acquires state variables from a user terminal 2. The state variables are substances or organisms that configure an ecosystem model to be generated. In the state variables, substance amounts or biological amounts vary over time. The processing device 1 acquires nutrients, diatom, rotifer, sea bream, and detritus as state variables.

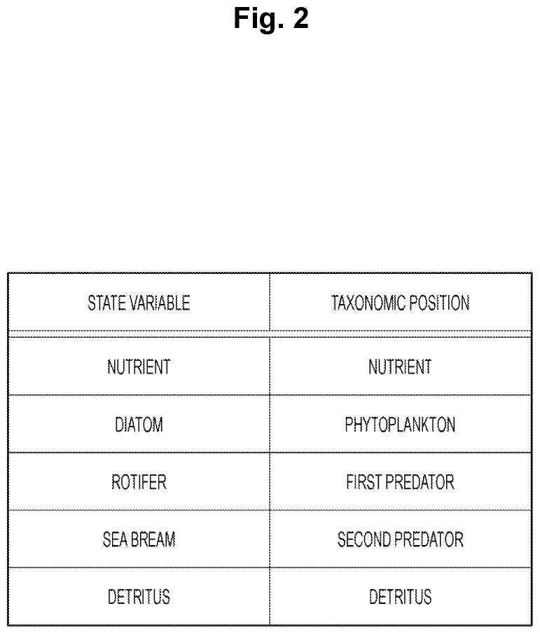

In step S2, the processing device 1 generates a model from the acquired state variables. The processing device 1 identifies a taxonomic position for each state variable. As illustrated in FIG. 2, in the processing device 1, taxonomic position of the nutrients is “nutrient”, a taxonomic position of the diatom is “phytoplankton”, taxonomic positions of the rotifer and the sea bream are “predators”, and a taxonomic position of detritus is “detritus”. Here, since the taxonomic positions of the rotifer and the sea bream are “predators”, the processing device 1 clarifies a predation relationship between the predators. In this case, since the sea bream feeds on rotifer, the processing device 1 sets the rotifer as the “first predator” and the sea bream as the “second predator”.

The processing device 1 identifies a number for each classification from the taxonomic position of each state variable. In the example illustrated in FIG. 2, the classification “nutrients” is 1, the classification “phytoplankton” is 1, the classification “predator” is 2, and the classification “detritus” is 1.

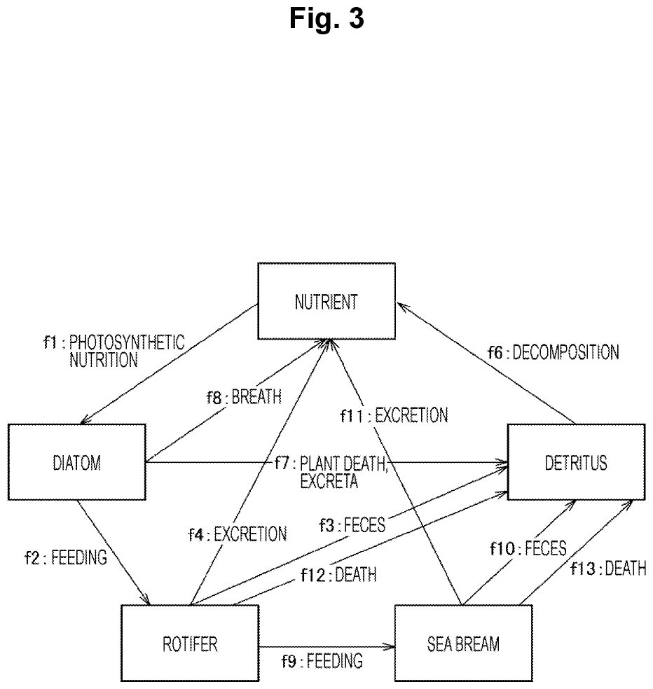

The processing device 1 acquires a template of the model from the number for each classification. The processing device 1 generates a model by incorporating the state variables into the acquired template. FIG. 3 illustrates a model generated here. In the model illustrated in FIG. 3, the state variable acquired in step S1 is set to each substance or organism. Flows f1 to f13 indicate relationships between the elements. The flow is a function indicating a balance of each substance amount or each biological amount per unit time. The functions f1 to f13 are shown in advance in the template.

In step S3, the processing device 1 transmits model data for identifying the model illustrated in FIG. 3 to the user terminal 2. The user terminal 2 draws the received model data and displays the model illustrated in FIG. 3. The user checks the displayed model, checks whether correction is required, and inputs the result to the user terminal 2. When an instruction with no correction is input from the user in step S4, the user terminal 2 transmits a model determination notification to the processing device 1 in step S8.

When an instruction with correction is input from the user in step S4, the user terminal 2 transmits a flow correction instruction to the processing device 1 in step S5. The flow correction instruction includes correction content input by the user. Here, it is assumed that the user gives an instruction to add a flow of “f15: residual feed” from the rotifer to the detritus and to delete a flow f13. The flow f13 is a flow indicating that when the sea bream that is the second predator dies, the sea bream turns into detritus. In this model, since the sea breams are a cultivation target and are shipped without death, it is appropriate to delete the flow f13.

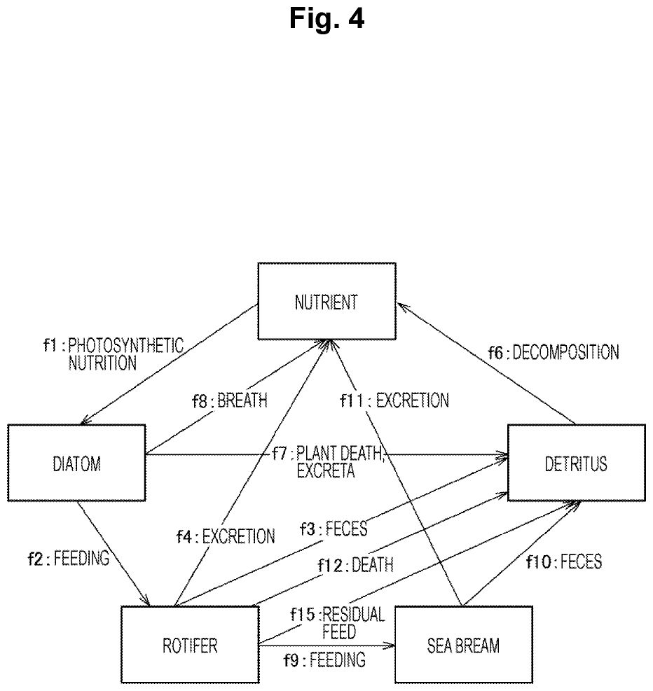

In step S6, the processing device 1 corrects the model illustrated in FIG. 3 in response to the flow correction instruction acquired in step S5. The processing device 1 generates a correction model illustrated in FIG. 4.

In step S7, the processing device 1 transmits the model data for identifying the model illustrated in FIG. 4 to the user terminal 2. The user terminal 2 draws the received model data and displays the model illustrated in FIG. 4. The user checks the displayed model, checks whether correction is required, and inputs the result to the user terminal 2. When an instruction with no correction is input, the user terminal 2 transmits a model determination notification to the processing device 1 in step S8.

When the model determination notification is transmitted, in step S9, the processing device 1 ends the correction process of the most recently transmitted model. In step S10, the processing device 1 inquires of the user terminal 2 about conditions for prediction using the determined model. The conditions include an initial value of a variable, a value set to a constant, and a prediction period. In step S11, the user terminal 2 transmits the conditions input from the user to the processing device 1.

In step S12, the processing device 1 predicts an increase or decrease in the substance amount and the biological amount of each substance and organism according to the model determined in step S9 and the conditions acquired in step S11. In step S13, the processing device 1 transmits the substance amounts and the biological amounts predicted in step S12 to the user terminal 2.

The processing method according to the present disclosure can generate a marine ecosystem model according to any environment. It is possible to predict each substance amount and biological amount in the environment using the marine ecosystem model indicating any environment.

### Processing System

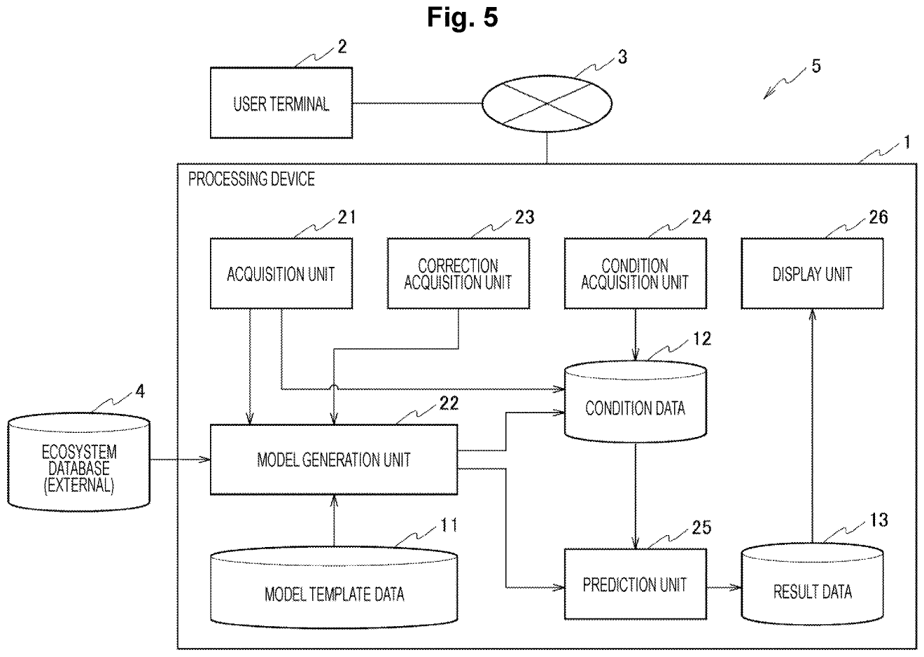

The processing device 1 according to the present disclosure and a processing system 5 in which the processing device 1 is used will be described with reference to FIG. 5.

The processing system 5 includes a processing device 1, a user terminal 2, and an ecosystem database 4. The processing device 1 and the user terminal 2 are connected to be able to communicate bidirectionally a communication network 3. The processing device 1 can refer to the ecosystem database 4.

The ecosystem database 4 is an information system related to distribution and diversity of marine organisms. The ecosystem database 4 indicates distribution and diversity data of global marine organisms by retrieving and integrating the data. The data of the ecosystem database 4 is based on the Darwin Core format that is a world standard format. The data of the ecosystem database 4 includes at least a taxonomic position, a distribution, and an appearance time. The ecosystem database 4 is, for example, an ocean biogeographic information system (OBIS: https://obis.org/).

### Processing Device

The processing device 1 includes data of model template data 11, condition data 12, and result data 13, and functions of an acquisition unit 21, a model generation unit 22, a correction acquisition unit 23, a condition acquisition unit 24, a prediction unit 25, and a display unit 26. Each piece of data is stored in a storage device such as a memory 902 or a storage 903. Each function is mounted in a CPU 901.

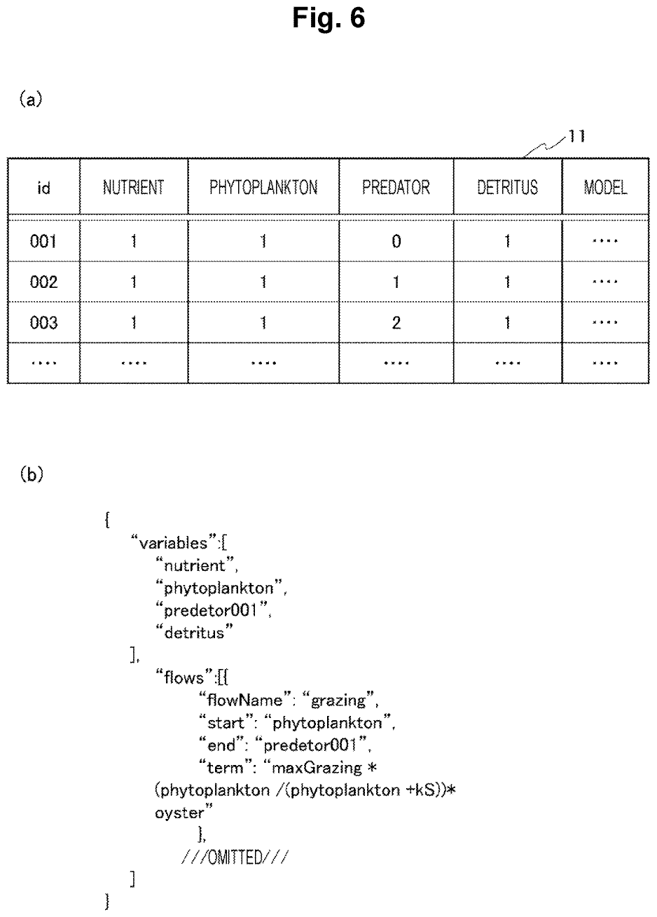

The model template data 11 is data for storing template data of various models generated in the present disclosure. As illustrated in FIG. 6(a), for example, the model template data 11 is associated with a number of each classification in the model drawn by each template.

As illustrated in FIG. 6(b), the template of the model in the model template data 11 defines classification of the state variables and the flow between the state variables. The template illustrated in FIG. 6(b) has nutrients, phytoplankton, a predator (predator001), and detritus as classifications of the state variables. The model illustrated in FIG. 6(b) associates a flow name, a starting point, an ending point, and a function for a flow generated between state variables. The function identifies a balance between the starting and ending state variables. This function is formed by the number of state variables, constants, and the like.

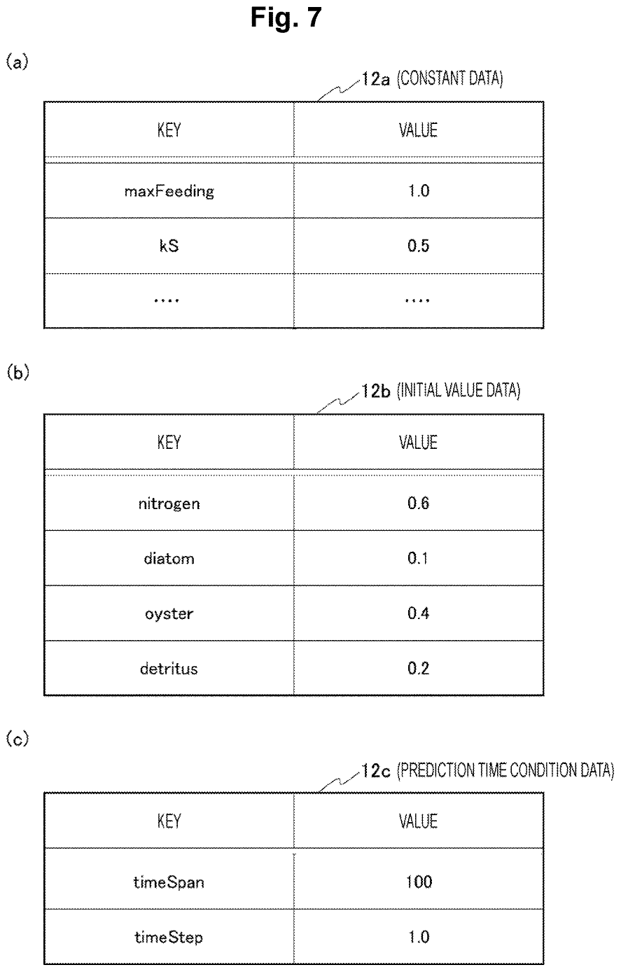

The condition data 12 stores conditions that are referenced to estimate a substance amount and biological amount from the model. As illustrated in FIG. 7, the condition data 12 includes constant data 12a, initial value data 12b, and prediction time condition data 12c. The constant data 12a includes a value of a constant referred to in the model. When the model template is identified by the model generation unit 22, a constant included in the model template is set as a key of the constant data 12a. When the user corrects the model and there is an unknown constant in the correction content, the unknown constant is set as a key of the constant data 12a. The initial value data 12b includes an initial value of the state variable referred to in the model. When the state variable is acquired by the model generation unit 22, the state variable is set as a key of the initial value data 12b. The prediction time condition data 12c is a period and a time interval in prediction.

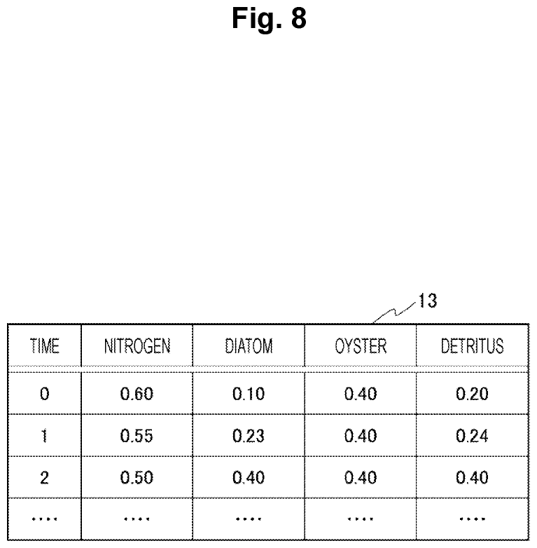

The result data 13 is data of the substance amount and the biological amount of each state variable predicted by the prediction unit 25. For example, as illustrated in FIG. 8, the result data 13 is a density value of each state variable for each day. The amount of each state variable can be calculated from the density of each state variable, a capacity of a water tank, and the like.

The acquisition unit 21 acquires the state variables that configures the ecosystem model from the user terminal 2. The acquisition unit 21 inputs the acquired state variable to the model generation unit 22. A process of the acquisition unit 21 corresponds to step S1 in FIG. 1.

The model generation unit 22 generates a model from the state variables acquired by the acquisition unit 21, and corrects the model in response to an instruction from the user terminal 2. This process corresponds to steps S2 and S3 and steps S6 and S7 in FIG. 1.

The model generation unit 22 first identifies the taxonomic positions of the state variables acquired by the acquisition unit 21 with reference to the ecosystem database 4 or the like. When a plurality of state variables belong to the classification of the predators, the model generation unit 22 identifies the first and second predators from the taxonomic position, and incorporates the first and second predators into the model template. The model generation unit 22 identifies an organism that is eaten and an organism that eats with respect to a relationship between two state variables of which classification is the predators. For example, when the state variables belonging to the predators are a rotifer and a sea bream, the rotifer is the “first predator” and the sea bream is the “second predator”.

The model generation unit 22 acquires the model template from the number of identified taxonomic positions for each classification. The model generation unit 22 associates the number of each state variable acquired by the acquisition unit 21 for each classification of nutrients, plankton, predator, and detritus. For example, when the state variables are nutrients*1, plankton*1, predator*1, and detritus*1, the model generation unit 22 acquires a template in which the number of classifications is one from the model template data 11.

The model generation unit 22 generates a model in which the state variables are incorporated into the acquired model template. The model generation unit 22 generates the model by setting the state variables in substance names and organism names in the template.

The model generation unit 22 outputs the generated model to the user terminal 2.

The correction acquisition unit 23 acquires a correction instruction for the flow from the user terminal 2. The correction acquisition unit 23 inputs the acquired instruction to the model generation unit 22. The process of the correction acquisition unit 23 corresponds to step S5 in FIG. 1.

When a flow correction instruction between the state variables is input from the user terminal 2, the model generation unit 22 corrects the model in response to the flow correction instruction. For example, when a flow name, a starting point, an ending point, and a function are input as an instruction to add a flow from the user terminal 2, the model generation unit 22 adds the flow from the input starting point to the ending point, and associates the flow name and the function as attributes of the flow. When an identifier of a flow to be deleted is input as an instruction to delete the flow from the user terminal 2, the model generation unit 22 deletes data of the flow corresponding to the input identifier of the flow from the model.

The condition acquisition unit 24 acquires data of conditions used in prediction by the model, such as initial values of variables used in a flow between the state variables. The condition acquisition unit 24 acquires a value of each condition illustrated in FIG. 7. The process of the condition acquisition unit 24 corresponds to step S11 in FIG. 1.

The prediction unit 25 predicts a change in the ecosystem model using the generated model and the condition such as the initial value acquired by the condition acquisition unit 24. The prediction unit 25 predicts the amounts of state variables for each time and records the amounts in the result data 13. The prediction process by the prediction unit 25 is described in Chapter 2 of Non Patent Literature 2. The process of the prediction unit 25 corresponds to step S12 in FIG. 1.

The display unit 26 transmits the result data 13 to the user terminal 2 and displays the result data. The process of the display unit 26 corresponds to step S13 in FIG. 1.

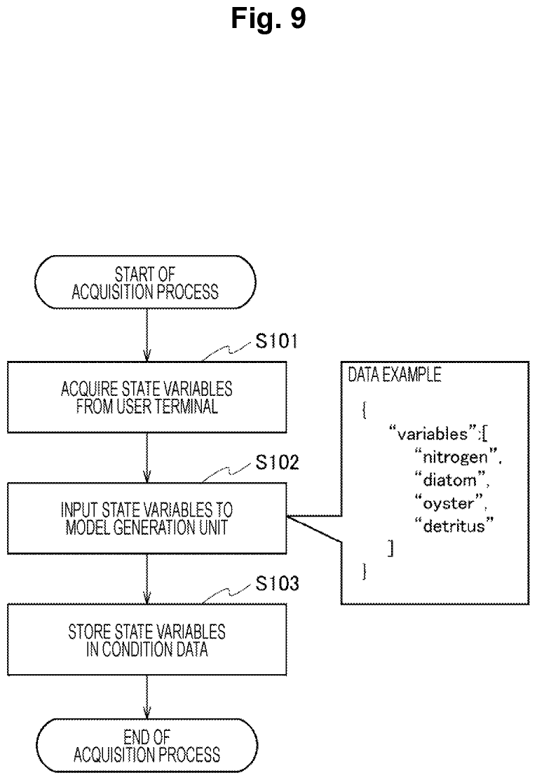

The process of each processing unit will be described with reference to FIGS. 9 to 12. The content and order of the processes described here are merely exemplary, and the present invention is not limited thereto.

First, an acquisition process by the acquisition unit 21 will be described with reference to FIG. 9.

In step S101, the acquisition unit 21 acquires the state variables corresponding to the substances and the organisms of the ecosystem model to be generated from the user terminal 2.

In step S102, the acquisition unit 21 inputs the state variables acquired in step S101 to the model generation unit 22. The acquisition unit 21 acquires, for example, “nitrogen”, “diatom”, “oyster”, and “detritus” as the state variables.

In step S103, the acquisition unit 21 stores the state variables acquired from the user terminal 2 in the condition data 12. The acquisition unit 21 sets the state variables in a key column of the initial value data of the condition data 12b illustrated in FIG. 7(b). At this time point, the initial value (value) of each state variable is not set.

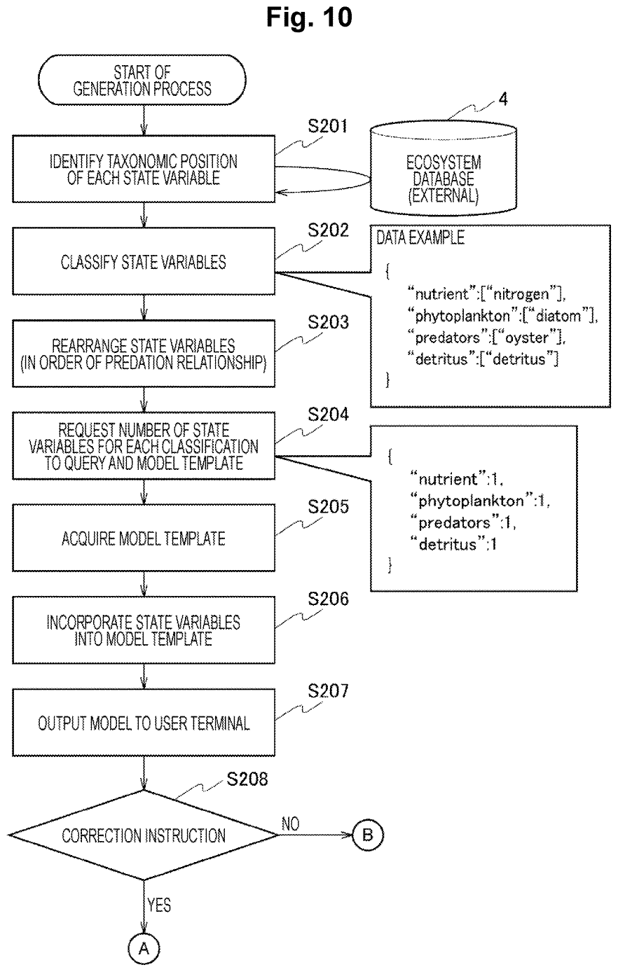

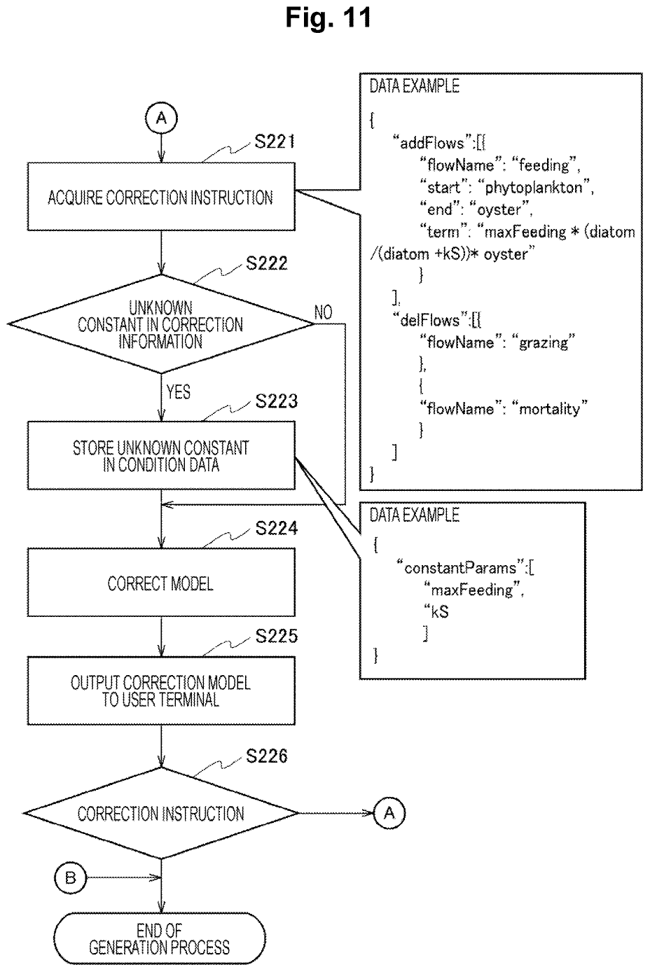

A generation process by the model generation unit 22 will be described with reference to FIGS. 10 and 11.

In step S201, the model generation unit 22 identifies the taxonomic position of each state variable input from the acquisition unit 21. In step S202, the model generation unit 22 classifies the state variables according to the taxonomic positions acquired in step S201. The model generation unit 22 classifies “nitrogen” into nutrients, “diatom” into phytoplankton, “oyster” into predator, and “detritus” into detritus.

In step S203, when a plurality of state variables belong to the classification of the predator, the model generation unit rearranges the state variables in the order of a predation relationship. Here, since there is only one state variable belonging to the predator, the process of step S203 will be omitted.

In step S204, the model generation unit 22 requests the number of state variables for each classification to a query and requests a model template from the model template data 11. For the query, nutrients are 1, plankton is 1, predators are 1, and detritus is 1. In step S205, the model generation unit 22 acquires a model template matching the query.

In step S206, the model generation unit 22 generates a model by incorporating the state variables into the model template acquired in step S205. In step S207, the model generation unit 22 outputs the model generated in step S206 to the user terminal 2.

In step S208, the model generation unit 22 determines whether a correction instruction has been input from the user terminal 2. When the correction instruction is input, the process proceeds to step S221. When the correction instruction is not input, the process ends.

In step S221, the model generation unit 22 acquires the correction instruction from the user terminal 2. Here, the correction instruction includes an instruction to add a feeding flow having a starting point “plankton” and an ending point “oyster”, and an instruction to delete each flow having a flow name of predation and death. In step S222, when the acquired correction instruction includes an unknown constant in the instruction to add or correct the flow, the model generation unit 22 sets the unknown constant as a key of the constant data 12a of the condition data 12 in step S223. The value of the unknown constant is designated by the condition acquisition unit 24 from the user. The model generation unit 22 sets constants maxFeeding and kS included in the instruction to add a flow as keys of the constant data 12a.

In step S224, the model generation unit 22 corrects the model in response to the correction instruction acquired in step S221. In step S225, the model generation unit 22 outputs the corrected model to the user terminal 2. In step S226, the model generation unit 22 determines whether a correction instruction has been input from the user terminal 2. When the correction instruction is input, the process proceeds to step S221. When the correction instruction is not input, the process ends.

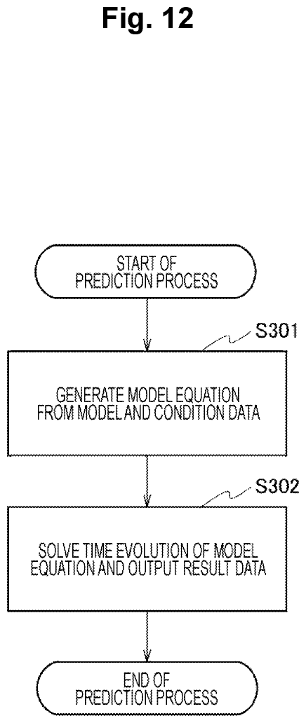

A prediction process by the prediction unit 25 will be described with reference to FIG. 12.

In step S301, the prediction unit 25 generates a model equation from the model generated by the model generation unit 22 and the condition data 12. In step S302, the prediction unit 25 solves a time evolution of the model equation generated in step S301. The model generation unit 22 generates and outputs result data 13 with which the number of state variables for each time is associated.

The processing device 1 according to the present disclosure can generate any ecosystem model according to the environment. At this time, since the user may input restricted items such as state variables in the ecosystem model and a condition related to prediction, a burden on the user becomes small. By generating any ecosystem model, it is possible to predict a change in a substance amount and a biological amount in the environment artificially configuring a part of a marine ecosystem on land or the like, such as the ecosystem aquaponics.

Accordingly, in the ecosystem aquaponics or the like, a production amount can be easily predicted, and a profit due to maximization of the production amount can be expected.

In the ecosystem aquaponics or the like, the processing device 1 can optimize an addition amount of nutrients or the like and an amount of circulating water with respect to a necessary amount of production. Accordingly, a reduction of substance cost can be expected. Since the addition amount is optimized, it is not necessary to manually adjust an additive during operation, and a reduction of operation cost can be expected.

Development of an aquaculture industry utilizing an environmental system can contribute to a reduction in an environmental load such as utilization of aquaculture water. Ultimately, utilization in closed ecosystem life support systems in a space station or a space station can be expected.

As the processing device 1 according to the above-described embodiment, for example, a general-purpose computer system that includes a central processing unit (CPU: processor) 901, a memory 902, a storage 903 (a hard disk drive (HDD) or a solid state drive (SSD) ), a communication device 904, an input device 905, and an output device 906 is used. In the computer system, each function of the processing device 1 is implemented by the CPU 901 executing a program loaded on the memory 902.

The processing device 1 may be mounted in one computer or may be mounted in a plurality of computers. The processing device 1 may be a virtual machine mounted in a computer.

A program of the processing device 1 can be stored in a computer-readable recording medium such as an HDD, an SSD, a universal serial bus (USB) memory, a compact disc (CD), or a digital versatile disc (DVD) or can be distributed via a network. The computer-readable recording medium is, for example, a non-transitory recording medium.

The present disclosure is not limited to the above embodiment, and various modifications can be made within the scope of the spirit of the present invention.

### REFERENCE SIGNS LIST

1 Processing device
2 User terminal
3 Communication network
4 Ecosystem database
5 Processing system
11 Model template data
12 Condition data
13 Result Data
21 Acquisition unit
22 Model generation unit
23 Correction acquisition unit
24 Condition acquisition unit
25 Prediction unit
26 Display unit
901 CPU
902 Memory
903 Storage
904 Communication device
905 Input device
906 Output device

1. A processing device comprising:
an acquisition unit, implemented using one or more computer processors, configured to acquire state variables that configure an ecosystem model; and
a model generation unit, implemented using one or more computer processors, configured to identify taxonomic positions of the acquired state variables, acquire a model template from a number of the identified taxonomic positions for each classification, and generate a model in which the state variables are incorporated in the acquired model template.

2. The processing device according to claim 1, wherein, based on a plurality of state variables belonging to a classification of predators, the model generation unit is configured to identify first and second predators from the taxonomic positions and incorporate the first and second predators into the model template.

3. The processing device according to claim 1, wherein the model generation unit is configured to output the model and correct the model in response to a correction instruction based on the correction instruction of a flow between the state variables being input.

4. The processing device according to claim 1, comprising:
a condition acquisition unit, implemented using one or more computer processors, configured to acquire an initial value of a variable used in a flow between the state variables; and
a prediction unit, implemented using one or more computer processors, configured to predict a change in the ecosystem model using the generated model and the acquired initial value.

5. The processing device according to claim 4, wherein, based on an instruction to add the flow between the state variables being input and an unknown constant being in the added flow, the condition acquisition unit is configured to further acquire an initial value of the unknown constant.

6. A processing method comprising:
acquiring, by a computer, state variables that configure an ecosystem model; and
identifying, by the computer, taxonomic positions of the acquired state variables, acquiring, by the computer, a model template from a number of the identified taxonomic positions for each classification, and generating, by the computer, a model in which the state variables are incorporated in the acquired model template.

7. A non-transitory computer readable medium storing a program, that upon execution, causes a computer to perform operations comprising:
acquiring state variables that configure an ecosystem model; and
identifying taxonomic positions of the acquired state variables;
acquiring a model template from a number of the identified taxonomic positions for each classification; and
generating a model in which the state variables are incorporated in the acquired model template.
